(19) United States
(12) Patent Application Publication
(10) Pub. No.: US 2002/0168800 A1
(43) Pub. Date: Nov. 14, 2002

(54) Method for forming a sensing apparatus having a cut-plane sensor and signal conditioner formed in a seamless monolithic substrate

(76) Inventors: Marshall E. Smith JR., Eaton, FL (US); Richard W. Stettler, Winter Haven, FL (US); Peter U. Wolff, Winter Haven, FL (US)

Correspondence Address: Allen, Dyer, Doppelt, Milbrath & Gilchrist, P.A., Suite 1401, 255 South Orange Avenue, P.O. Box 3791, Orlando, FL, 32802-3791, US

(21) Appl. No.: 10/136,461

(22) Filed: May 1, 2002

Related U.S. Application Data
(60) Provisional application No. 60/287,763, filed on May 1, 2001.
(60) Provisional application No. 60/288,312, filed on May 2, 2001.
(60) Provisional application No. 60/288,313, filed on May 2, 2001.
(60) Provisional application No. 60/287,856, filed on May 1, 2001.
(60) Provisional application No. 60/288,281, filed on May 2, 2001.
(60) Provisional application No. 60/288,279, filed on May 2, 2001.

(51) Int. Cl. H01L 21/82; H01L 21/00

(52) U.S. Cl. 438/128; 438/129; 438/50

(57) ABSTRACT

A method for forming a sensing apparatus having a sensor and signal conditioner angled relative to each other at a predetermined angle and formed in a seamless monolithic semiconductor substrate is provided. The sensor and the signal conditioner are formed on distinct surface portions of a single seamless monolithic semiconductor substrate. The sensor, moreover, can be formed in the cut plane of the seamless monolithic semiconductor substrate. The signal conditioner correspondingly can be formed in a wafer surface of the same seamless monolithic semiconductor substrate. The seamless monolithic semiconductor substrate further can be mounted on a mounting base and at least the signal conditioner encapsulated in an encapsulation to provide a protective cover. An additional conductor connected to the signal conditioner and extending outwardly from the encapsulation can connect the sensing apparatus to a remote electrical device such as a sensing monitor.

### RELATED APPLICATIONS

This application claims priority to Provisional Application Serial No. 60/287,763 filed May 1, 2001, and incorporates by reference the disclosures of Provisional Application No. 60/288,312 filed May 2, 2001, Provisional Application Serial No. 60/288,313 filed May 2, 2001, Provisional Application Serial No. 60/287,856 filed May 1, 2001, Provisional Application Serial No. 60/288,281 filed May 2, 2001, and Provisional Application Serial No. 60/288,279 filed May 2, 2001.

### FIELD OF THE INVENTION

The present invention relates to the field of sensing apparatuses and, more particularly, to the field of sensing apparatuses and methods for forming sensing apparatuses.

### BACKGROUND OF THE INVENTION

Sensing apparatuses are widely used in mechanical and electrical systems for detecting and measuring a myriad of physical or chemical phenomena. Among the various uses for such devices, for example, are sensing the presence and intensity of electrical and magnetic fields. Sensing devices are also commonly used, for example, to detect mechanical forces, measure the temperature or flow of a liquid or gas, or register the acceleration of a solid body. Designers of sensing devices confront conflicting requirements in the quest for an efficient and effective sensing apparatus. Typically, the mechanical and electrical systems in which such sensing devices are utilized are subject to various conditions that can adversely affect the operating performance of the apparatus. These adverse conditions include, for example, extreme accelerations and vibrations, intense temperature variations, corrosive chemicals, and electrostatic discharges.

Thus, the sensing apparatus must have a sufficiently robust structural integrity if it is to perform optimally in such harsh environments and under such extreme conditions. Secondly, because the mechanical and electrical systems in which sensing devices are commonly used are themselves becoming ever more compact, the allocation of space for the included sensing apparatus must be optimized. Therefore, in addition to being structurally robust, an optimally designed sensing apparatus must also be as small as possible. This latter requirement is an especially challenging design consideration given that the number of components needed for such mechanical and electrical systems can increase as the systems become increasingly complex and are employed for an ever greater number of signaling tasks. Thirdly, as sensing apparatuses are tasked to provide an ever greater number of signaling functions in increasingly varied settings, there is a greater challenge to keep signal conditioning circuitry from becoming overly cumbersome and complex as it powers the sensing component, conditions the sensing signal, and provides signal amplification to overcome electromagnetic fields or extraneous noise factors. And finally, the sensing apparatus should be efficient in terms of being capable of cost-efficient installation as well as being simple to service.

Thus, an optimally designed field sensing apparatus is one that is rugged in terms of structure, small in size, capable of providing accurate signal responses to complex physical phenomena, and yet designed with sufficient simplicity to be easily installed and maintained in a mechanical or electrical system. The challenge posed for designers lies in the fact that these requirements frequently conflict. A small, rugged sensing apparatus would contain a minimum number of electronic devices so as to reduce the probability that a connection will fail due to vibration, shock, or temperature-induced expansions or contractions. Weighing against this objective, however, is the requirement that the sensing apparatus be sophisticated enough to detect and process sensed signals that are discernable despite external noise. This latter requirement, however, ordinarily necessitates complex and sometimes cumbersome signal conditioning circuitry that accordingly increases the complexity and size of the sensing apparatus. A major design goal, therefore, is to provide a sufficiently sophisticated set of circuitry that is complex enough to discern and respond to physical phenomena without adversely affecting its structural integrity by unduly increasing the number and complexity of electrical connections, all while simultaneously making the sensing apparatus as small as possible.

The typical sensing device is a set of electrical components manufactured on a semiconductor substrate or “chip” cut from a semiconductor wafer. Temperature changes exert a strong influence on the electrical conductivity and other properties affecting the devices' operating characteristics. Because most of the mechanical and electrical systems in which a sensing apparatus is utilized are exposed to extreme temperature variations, the effects of temperature must be controlled in the sensing apparatus. This ordinarily is the function of the signal conditioning circuitry which amplifies or otherwise conditions the signal generated by the sensing component. The signal conditioner is also needed for other functions such as compensating for a signal that is too low to overcome noise effects and to increase the signal for relay to a remotely located monitor. As the number and complexity of signal conditioning functions increase, so, too, does the size of the signal conditioning circuitry. Accordingly, the overall size of the sensing apparatus increases as well. Therefore, the signal conditioning circuitry can be a limitation on the design of a reduced-size apparatus.

A further limiting condition arises because the sensitivity of the sensing apparatus is affected by the orientation of the sensing component relative to the force or field to be sensed. Maximum sensing sensitivity requires a precise orientation of the sensing component. If the sensing component and the signal conditioning circuitry are formed on the same surface plane of a semiconductor, the signal conditioning circuitry, of necessity, will have the same orientation as the sensing component. Orientation of both the sensing component and the signal conditioning circuitry in the identical plane produces a larger cross section for the sensing apparatus than could otherwise be achieved by orienting the sensing component to the field and separately orienting the signal conditioning circuitry so as to reduce the overall dimension of the sensing apparatus cross section.

Various devices have attempted to deal with some of the multiple, competing objectives of an efficient, compact sensing apparatus. Applicants' own U.S. Pat. No. 6,002,252 titled Compact Sensing Apparatus Having Transducer and Signal Conditioner with a Plurality of Mounting Pins and U.S. Pat. No. 6,187,609 titled Compact Sensing Apparatus Having Reduced cross Section and Methods of Mounting, for example, teach the advantages of methods for forming a sensing apparatus having a transducer and signal conditioning circuitry connected via wire pins and mounted on distinct surfaces at a predetermined angle so as to reduce the overall the lengthwise extent of the sensing apparatus. Applicants' U.S. Pat. No. 5,670,886, moreover, discloses an apparatus having signal conditioning circuitry formed in a surface portion of single semiconductor substrate and a magnetic sensing element formed in an orthogonal edge of the same substrate and connected via metal conductors to the signal conditioning circuitry.

Devices employed in the fields of digital imaging and optical detecting also have attempted, with varying degrees of success, to deal with many of the same problems confronting designers of compact sensing apparatuses and facing conflicting efficiency objectives in terms of apparatus size, sensing element orientation, and structural integrity of the device. U.S. Pat. No. 5,869,896 issued to Baker et al. and titled Packaged Electronic Module and Integral Sensor Array, for example, describes attempts to make a small, lightweight, real-time, wide-field view imager by constructing a “monolithic electronic module” formed from “multiple bare semiconductor chips (i.e., semiconductor dies), laminated together into a unified stack.” A sensor is then “coupled” to the stack and connected to other circuitry contained thereon through a thin-film metallization layer along an edge. U.S. Pat. No. 4,403,238 issued to Clark and titled Detector Array Focal Plane Configuration describes similarly describes “a stack, or sandwich, comprising numerous silicon chips, or substratess, escured together by suitable adhesive material.”

More specifically, Clark describes an electro-optical detector formed from “a multiplicity of layers” of a semiconductor and mounted on a supporting block. A detector “mosaic” is then coupled to the stack similar to the device in Baker et al.

Notwithstanding these attempts to deal with the competing constraints and objectives of an efficient compact sensing apparatus, there remains a need for a device not requiring the stacking or sandwiching of multiple semiconductor layers to which a sensor must be coupled. Stacked layers pose problems in terms of both the effectiveness and reliability of the device as well as the efficiency in forming such devices. More specifically, increasing the number of layers to accommodate the device's required circuitry increases the discrete electrical connections that must be formed and the number of physical couplings of semiconductor layers that must be made. There is, accordingly, increased risk that the connections can be undone or the layers uncoupled whenever the device is subjected to even the ordinary stresses encountered in most standard operating modes. This risk increases virtually in direct correlation to the number of layers and connections required to a multi-layered device. In addition, the separate forming steps rises in virtual lock-step as each new layer must be formed and then electrically coupled in building the stack. These additional steps are especially burdensome if one is attempting to form an integral substrate having a multi-layered surface formed into a single edge having a precise angle as would be necessary if one were attempting to position the sensor and related conditioning circuitry on two distinct surfaces at a predetermined angle.

### SUMMARY OF THE INVENTION

The various method aspects of the present invention include a method for forming a compact sensing apparatus on a single monolithic substrate. The single semiconductor substrate can be cut from a wafer by conventional means such as with a diamond saw cutter, but preferably, is formed by cutting the semiconductor wafer by delivering high concentrations of energy along dimensions of the wafer corresponding to dimensions of the substrate to be cut from the wafer. Such cutting at least partially alleviate cracks in the substrate and at least partially smooths the top and end surfaces of the substrate while also at least partially straightening the angled edges of the substrate. Preferably, the energy delivered is in the form of coherent electromagnetic radiation generated by a laser and thus conveyed for cutting the wafer as a narrow beam of light energy. The single semiconductor substrate also can be annealed following cutting from the semiconductor wafer to further alleviate cracks in the substrate and the surfaces of the substrate.

The method includes forming an insulation layer on a semiconductor substrate having a top substrate surface and an end substrate surface oriented with respect to each other at a predetermined angle greater than one hundred eighty (180) degrees, the predetermined angle being defined as previously to be the angle of rotation between an initial plane extending substantially parallel to the top substrate surface and an imaginary terminal plane extending substantially parallel to the end substrate surface. The insulation layer is formed in a position adjacent the end substrate surface and preferably has a thickness sufficient to ensure that the apparatus retains an insulation layer despite any diffusion of the semiconductor material of the substrate into the insulation layer that may occur during formation of the compact sensing apparatus.

The method further includes the step of forming a sensor on the end surface of the single monolithic semiconductor substrate. The method preferably also includes applying a temporary protective passivation layer over the monolithic substrate over at least the sensor to protect the sensor during subsequent formation of the signal conditioner. The method further comprises forming a signal conditioner electrically connected to the sensor on the same semiconductor substrate and formed on the top substrate surface of the same monolithic semiconductor substrate.

The method for forming a compact sensing apparatus, moreover, can include forming a conductive passivation region positioned between the sensing component and the signal conditioner. The conductive passivation region preferably is formed by a metal layer that can be etched to form at least one trace connection between the sensing component and the signal conditioner. Alternatively, the conductive region can be formed by creating a layer of conductive epoxy that can be etched to form at least one electrical connection between the sensing component and the signal conditioner.

A further method aspect of the present invention is provided for efficiently and economically forming a plurality of compact sensors. The method includes forming a plurality of sensors on a single strip of semiconductor material, the strip having a top surface and an end surface oriented with respect to each other at a predetermined angle greater than one hundred eighty (180) degrees. Again, the predetermined angle is defined as the angle of rotation between an imaginary initial plane extending substantially parallel to the top surface and an imaginary terminal plane extending substantially parallel to the end surface. Preferably, the plurality of sensors are formed on the end surface or the strip of semiconductor material. The method further includes forming a plurality of signal conditioners on the same semiconductor strip. Each of the plurality of signal conditioners is preferably formed on the top surface of the same strip and electrically connected to a corresponding sensor formed on the same strip. The plurality of sensors and corresponding signal conditioners having been formed on the single strip of semiconductor material, the strip is cut at predetermined intervals to form a plurality of compact sensing apparatuses, each sensing apparatus comprising a sensor and a corresponding signal conditioner electrically connected to the corresponding sensor positioned on a single monolithic substrate.

Preferably, the semiconductor strip is cut from a semiconductor wafer that itself has been sliced from a silicon crystal ingot. Moreover, the lateral extent of the strip is preferably equal to the lengthwise extent of each of the sensing apparatuses that ultimately is formed by the method.

Once each of the plurality of compact sensing apparatuses has been formed and cut from the single semiconductor strip, each such apparatus can be mounted on a base. Moreover, each mounted sensing apparatus can be positioned within a housing that encases at least a portion of the mounted sensing apparatus.

### BRIEF DESCRIPTION OF THE DRAWINGS

Some of the features, advantages, and benefits of the present invention having been stated, others will become apparent as the description proceeds when taken in conjunction with the accompanying drawings in which:

FIG. 1A is a perspective view of a semiconductor wafer being sliced from a semiconductor ingot for forming a sensing apparatus according to the present invention;

FIG. 1B is a perspective view of a semiconductor wafer from which a plurality of seamless semiconductor substrates is cut for forming a plurality of sensing apparatuses according to the present invention;

FIG. 1C is perspective view of a plurality of seamless semiconductor substrates from which a plurality of sensing apparatuses is formed according to the present invention;

FIG. 1D is a perspective view of a plurality of seamless semiconductor substrates on which are formed a plurality of sensors is formed for forming a plurality of sensing apparatuses according to the present invention;

FIG. 1E is a perspective view of a plurality of semiconductor substrates on which a plurality of sensors and corresponding signal conditioners is formed according to the present invention;

FIG. 1F is a perspective view of a plurality of sensing apparatuses each having a sensor and signal conditioner formed in a seamless semiconductor substrate according to the present invention;

FIG. 2A is a perspective view of a semiconductor wafer being sliced from a semiconductor ingot for forming a sensing apparatus according to the present invention;

FIG. 2B is a perspective view of a semiconductor wafer from which a plurality of seamless semiconductor substrates is cut for forming a plurality of sensing apparatuses according to the present invention;

FIG. 2C is perspective view of a plurality of seamless semiconductor substrates from which a plurality of sensing apparatuses is formed according to the present invention;

FIG. 2D is a perspective view of a plurality of seamless semiconductor substrates on which are formed a plurality of sensors is formed for forming a plurality of sensing apparatuses according to the present invention;

FIG. 2E is a perspective view of a plurality of sensing apparatuses each having a sensor and signal conditioner formed in a seamless semiconductor substrate according to the present invention;

FIG. 3 is a perspective view of a sensing apparatus according to the present invention;

FIG. 4 is a side elevational view of a sensing apparatus according to the present invention;

FIG. 5 is perspective view a sensing apparatus according to the present invention;

FIG. 6 is a top plane cross sectional view taken along line 6-6 in FIG. 5 of a sensing apparatus according to the present invention;

FIG. 7 is perspective view of a sensing apparatus according to the present invention;

FIG. 8 is a side cross sectional view taken along line 8-8 in FIG. 7 of a sensing apparatus according to the present invention;

FIG. 9 is a side elevational view of a sensing apparatus according to the present invention;

FIG. 10 is schematic flow of a method for forming a sensing apparatus having a sensor and signal conditioner angled relative to each other and formed in a seamless monolithic semiconductor substrate according to the present invention;

FIG. 11 is schematic flow of a method for forming a plurality of sensing apparatuses each having a sensor and signal conditioner angled relative to each other and formed in a seamless monolithic semiconductor substrate according to the present invention; and

FIG. 12 is a perspective view of a sensing apparatus according to the present invention illustrating a predetermined angle for a cut plane.

### DETAILED DESCRIPTION OF THE PREFERRED EMBODIMENT

The present invention will now be described more fully hereinafter with reference to the accompanying drawings which illustrate preferred embodiments of the invention. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, the prime notation, if used, indicates similar elements in alternative embodiments.

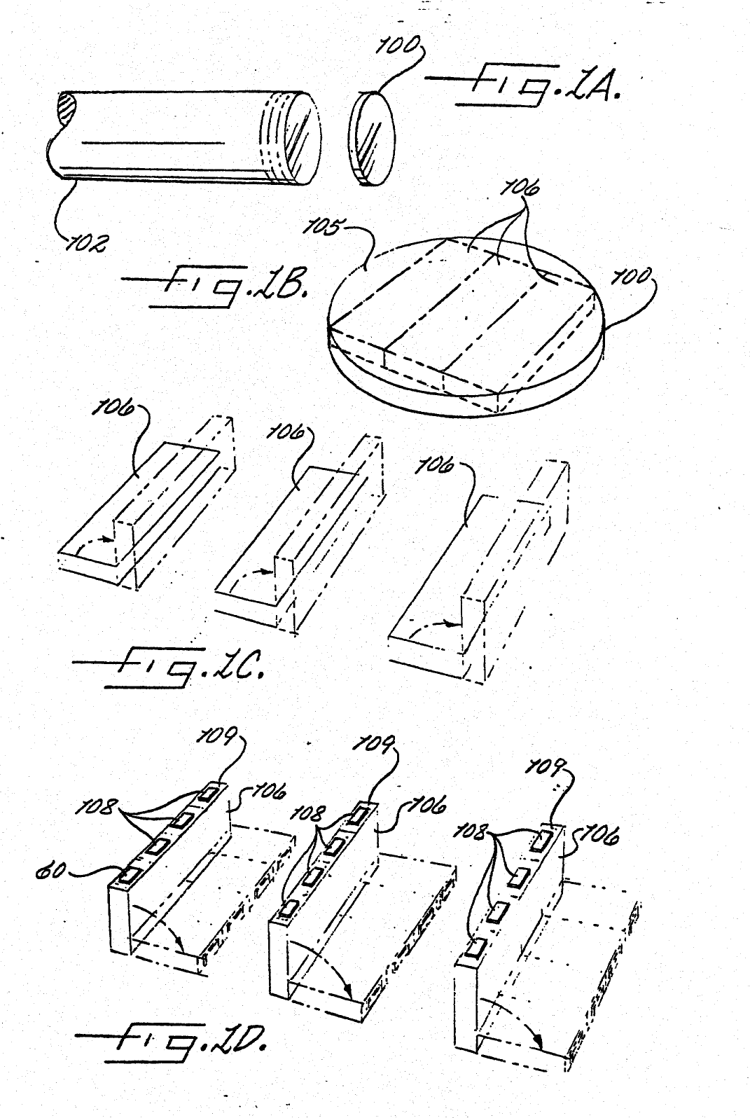

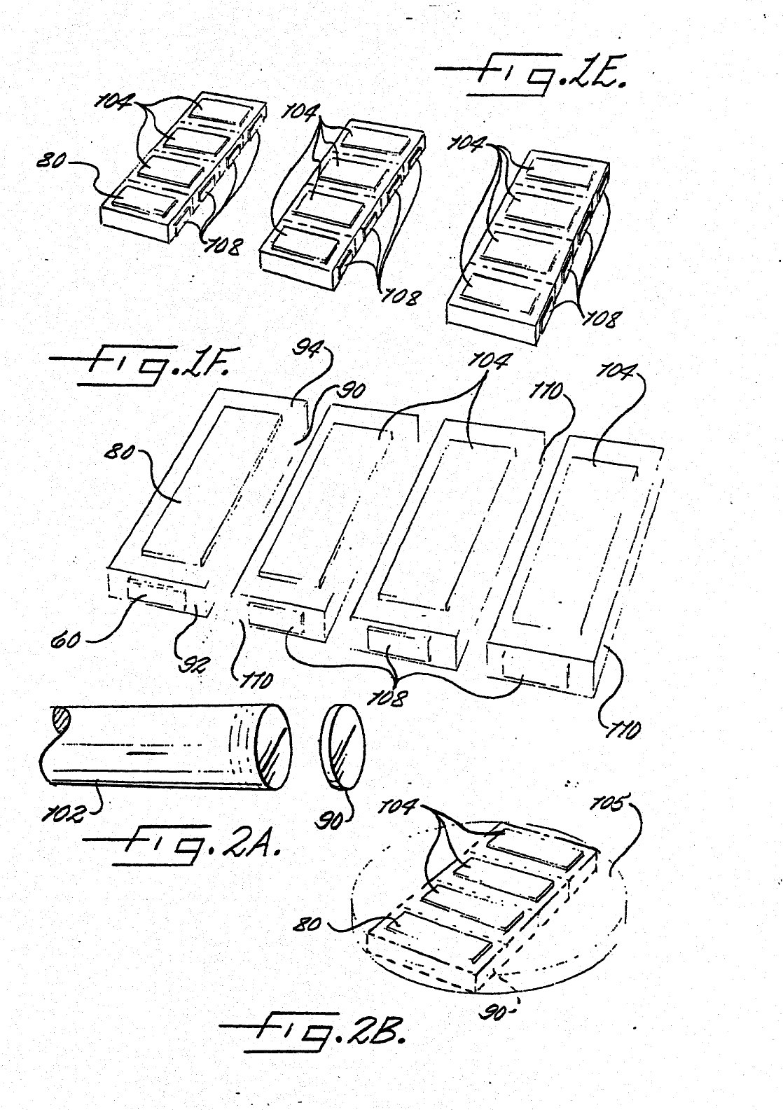

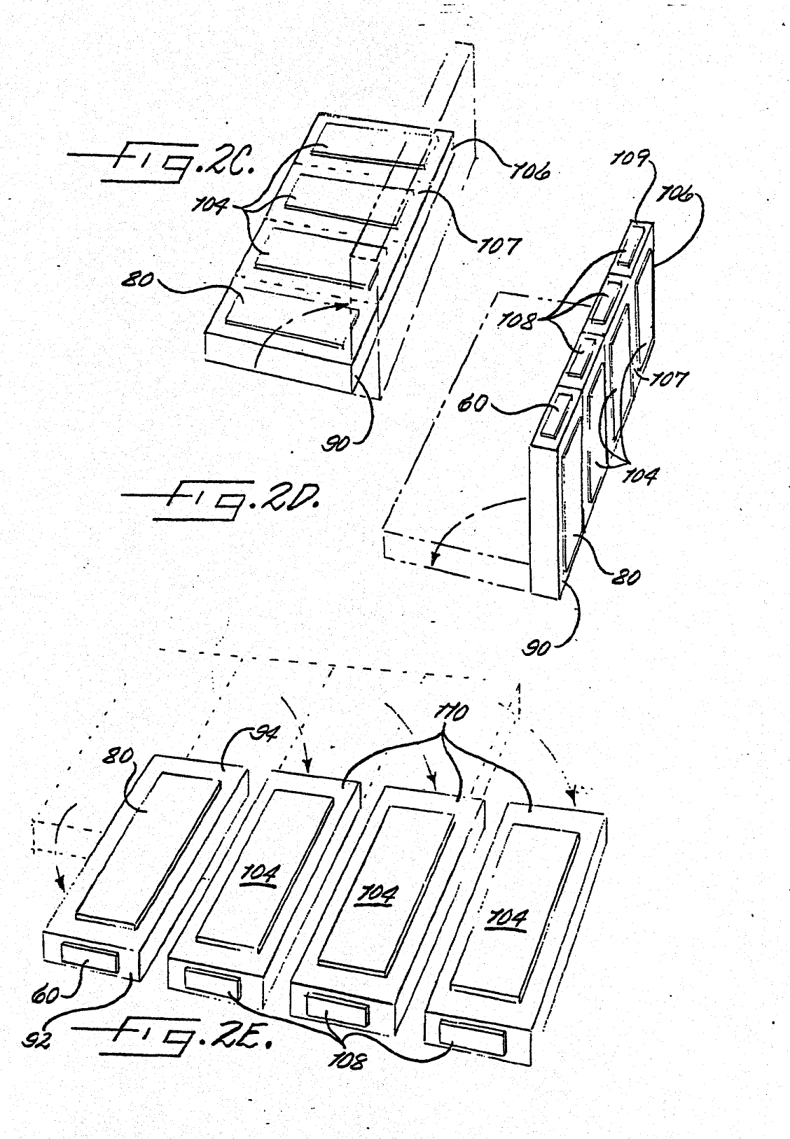

FIGS. 1-3. illustrates a compact sensing apparatus 40 comprising a sensor 60 and, electrically connected to the sensor, signal conditioning circuitry defining a signal conditioner 80. Both the sensor 60 and the signal conditioner 80 are formed in a single, seamless monolithic substrate 90. The sensor 60, more specifically, is formed on a cut plane 92 (defined explicitly below) of the seamless monolithic substrate 90, and the signal conditioner 80 is formed on a wafer surface 94 of the same seamless monolithic substrate 90. The seamless monolithic substrate 90 is formed from a semiconductor wafer 100, which itself typically will have been sliced from an ingot of semiconductor material 102 as will be readily understood by those familiar with the art of manufacturing semiconductor devices.

As further illustrated in FIGS. 1-3, the sensing apparatus 40 comprising a sensor 60 formed on a cut plane 92 of a seamless monolithic substrate 90 and a corresponding signal conditioner 80 formed on the wafer surface 94 of the same seamless monolithic substrate 90 is but one of several such sensing apparatuses 40, 110 that can be formed from the same semiconductor wafer 100 sliced from a semiconductor ingot 102. Specifically, a plurality of primary substrates 106 is “cut” from a single semiconductor wafer 100 by slicing through opposing wafer surfaces of the semiconductor wafer 100. The cutting of the wafer 100 and subsequent separation of the portions so cut from the wafer 100 yield the plurality of primary substrates 106, each of which has at least one cut plane 92, 109 corresponding to internal portions of the wafer exposed by the cutting through of the wafer 100 to form each of the primary substrates 106. Each of the primary substrates 106 also has opposing wafer surfaces that correspond to portions of the wafer from which each substrate was cut.

A plurality of sensors 60, 108 is then formed on a cut plane 109 of each of the plurality of primary substrates 106. Subsequently, signal conditioning circuitry defining a plurality of signal conditioners 80, 104 is formed on wafer surfaces 107 of each of the plurality of primary substrates 106. The primary substrates 106 are then cut along dimensions between each of the sensors 60, 108 and corresponding signal conditioners 80, 104 to form a plurality of seamless monolithic semiconductor substrates 90, 110, each having a sensor 60, 108 and corresponding signal conditioner 80, 104 angled relative to each other and formed therein.

So formed, then, the seamless monolithic substrate 90 has two surfaces (portions of the opposing surfaces of the wafer 100 from which the substrate 90 has been cut), one defining the wafer surface 94 in which the signal conditioner 80 is formed, and at least one angled-edge portion forming a cut plane 92 in which the sensor 60 is formed. The cut plane 92, specifically, is parallel to a plane through which the wafer has been cut. The sensor 60 and the signal conditioner 80 are, therefore, angled relative to each other at a predetermined angle corresponding to the angle between the cut plane 92 and the wafer surface 94 in which the sensor 60 and signal conditioner 80, respectively, are formed.

A significant advantage of the present invention, accordingly, is the ability to angle the sensor 60 and the signal conditioner 80 relative to each other while forming both in the same uncut, seamless monolithic substrate 90. The function of the sensing apparatus 40 is to sense a particular physical stimulus. It will have greatest sensing sensitivity is oriented properly relative to the physical stimulus it is to sense. The sensing apparatus ordinarily does not operate in isolation, however, but as part of a system and hence should be as small as possible. An efficient sensing apparatus 40, therefore, is one which optimizes the trade-off between orientation of the sensor 60 relative to sensing stimuli so as to enhance sensing sensitivity, on one hand, while on the other hand simultaneously orienting the sensor 60 and the signal conditioner 80 relative to each other so as to reduce the overall dimensions of the sensing apparatus 40.

Moreover, operative efficiency is enhanced if the sensor 60 and signal conditioner 80 are formed in a single, seamless semiconductor substrate 90. For example, there is much less chance that when that mechanical stress will separate the sensor 60 from the signal conditioner 80 or break the necessary electrical connections between the sensor 60 and the signal conditioner 80 when the sensing apparatus 40 is employed in a harsh environment. Moreover, the conductive properties of the substrate are accordingly more reliable when the sensor 60 and the signal conditioner 80 are both formed in the single, seamless monolithic semiconductor substrate 90. Therefore, the present invention is uniquely advantageous in terms of permitting the sensor 60 and the signal conditioner 80 to be angled relative to each other on and formed in the same uncut, seamless monolithic substrate 90.

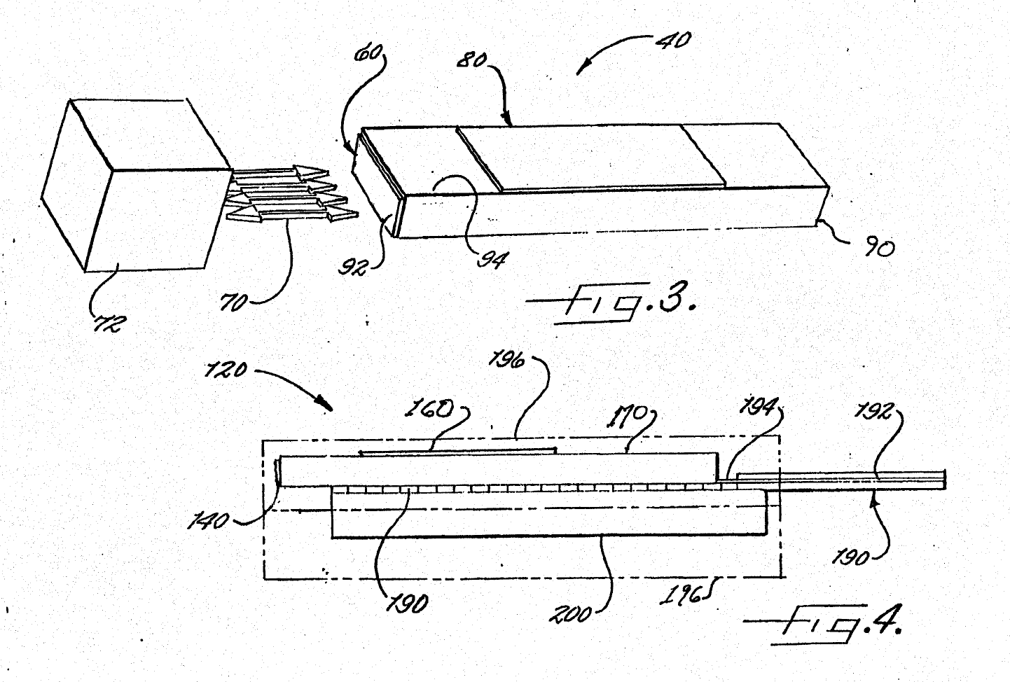

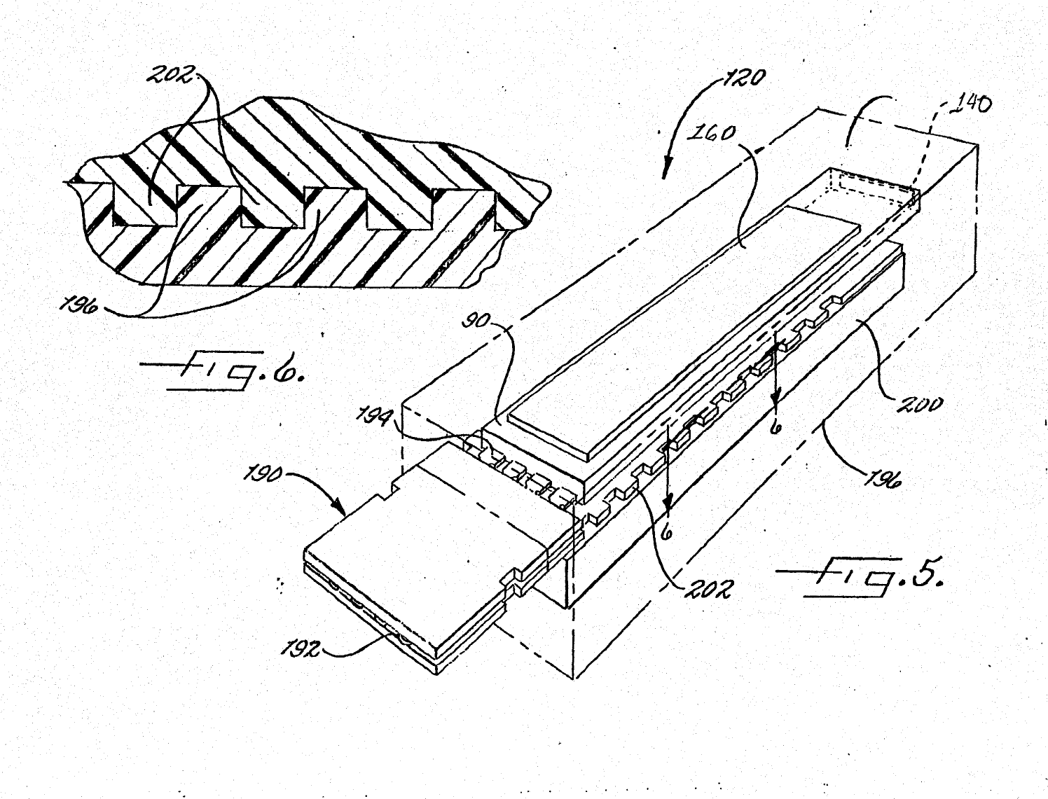

In many circumstances, the optimal trade-off of sensing sensitivity and sensing apparatus 40 compactness will be achieved if the sensor 60 and the signal conditioner 80—and, accordingly, the cut plane 92 and the wafer surface 94—are angled orthogonally to one another, as illustrated in FIGS. 1 and 2. Apparatuses having sensing elements and signal conditioners oriented orthogonally to one another are illustrated in Applicants' own U.S. Pat. No. 6,002,252 titled Compact Sensing Apparatus Having Transducer and Signal Conditioner With A plurality of Mounting Pins and U.S. Pat. No. 6,187,609 B1 titled Compact Sensing Apparatus Having Reduced Cross Section and Methods of Mounting. In FIG. 3, for example, the sensor 60 is positioned for maximum sensitivity perpendicularly to a sensed field 70 generated by object 72. The present invention, however, permits the sensor 60 and the signal conditioner 80 to angled relative to each other at any predetermined angle by orienting the cut plane 92 and the wafer surface 94 at substantially the predetermined angle as described above.

Generally, therefore, the cut plane and the wafer surface are oriented relative each other at a predetermined angle greater than one hundred eighty (180) degrees, the predetermined angle being defined as the angle of rotation between an imaginary initial plane extending substantially parallel to the wafer surface of the monolithic semiconductor substrate and an imaginary terminal plane extending substantially parallel to the cut plane of the semiconductor substrate, as illustrated in FIG. 3.

The sensor 60 can be any type of sensor that generates a sensing signal in response to a physical stimulus, the specific type of sensor depending on the nature of the physical stimulus. These include sensors for sensing electrical or magnetic fields, examples of which include Hall-effect cell, magnetoresistor, capacitive, and inductive sensors as well as electric current sensors. Similarly, electromagnetic sensors would include planar antenna arrays and light transducers, for example. Other sensors sense mechanical forces such as the flow or pressure of a liquid or gas, the mechanical stress or weight of an object, or the acceleration of body in motion, examples of which include a strain gauge, accelerometer, and tilt sensor. An example of an apparatuses having orthogonally oriented Hall elements and magnetoresistors is illustrated in Applicants' U.S. Pat. No. 65,670,886 titled Method and Apparatus for Sensing Proximity or Position on an Object Using Near-Field Effects.

A common feature of each of these various type sensors is that each generally exhibits a preferred orientation relative to the electric or magnetic field or the mechanical force being sensed, the preferred orientation being that which maximizes the sensitivity of the sensor. With respect to each, the ordinary environment in which the sensing apparatus is utilized will also dictate that the sensing apparatus be as small as possible. Therefore, the advantages of the present invention as described above will be equally great whatever the type of sensor 60 utilized in the sensing apparatus 40.

A sensing signal generated by the sensor 60 can be too weak to overcome external noise associated with the particular environment or system in which the sensing apparatus 40 is utilized. The sensing signal can be adversely affected by temperature variations in the environment or otherwise contain a large offset. Therefore, the sensing apparatus 40 further includes the signal conditioner 80 that, preferably, is formed in the wafer surface of the seamless monolithic semiconductor substrate 90 and is electrically connected to the sensor 60 to condition the signal generated by the sensor 60 in response to a predetermined physical stimulus as will be understood by those familiar in the art. The signal conditioner 80 can also boost the signal generated by the sensor 60 in order to convey it to a remote sensing monitor or other electrical device electrically connected to the sensing apparatus, generally being connected electrically directly to the signal conditioner 80 itself.

The sensing apparatus 40 preferably also includes at least one electrical conductor extending between the sensor 60 and the signal conditioner 80 to thereby provide a direct conductive path between the sensor 60 and the signal conditioner 80. Specifically, connecting traces are formed on the cut plane 92 and extend along the plane from the sensor 60 to the edge shared by the cut plane 92 and the wafer surface 94 of the seamless monolithic substrate 90. Similarly, connecting traces are formed on the wafer surface 94 and extend from the signal conditioner 80 and connect at the shared edge to the connecting traces formed on the cut plane 92 to electrically connect the sensor 60 and the signal conditioner 80. The connecting traces on the wafer surface, preferably, are metal traces formed by coating a portion of the wafer surface 94 to form a conductive passivation layer of metal and then etching away portions of the passivation layer so to leave only the desired metal traces that form conductive paths along the wafer surface 94. By contrast, the connecting traces formed on the cut plane preferably comprise defined polycrystalline regions. Each is formed of semiconductor material that has been highly doped to form conductive paths along the cut plane 92. Each such polycrystalline conductive path connects to a corresponding methal trace at the shared edge to form a direct conductive path between the sensor 60 and the signal conditioner 80. Thus, the sensing apparatus includes at least one conductive path along which a sensing signal generated in response to a physical stimulus by the sensor 60 is conveyed for signal conditioning to the signal conditioner 80.

FIG. 4 illustrates a second embodiment of a compact sensing apparatus 120 comprising a sensor 140 and a signal conditioner 160 electrically connected thereto via a conductive path, the sensor 140 and the signal conditioner 160, again, being formed in a seamless monolithic semiconductor substrate 170. As illustrated, the compact sensing apparatus 120 further comprises a second conductive path formed by an electrical connector 192 electrically connected to the signal conditioner 160 and extending therefrom to electrically connect to a preselected electrical device positioned remotely from the sensing apparatus 120. The electrical connector 192 preferably connects directly to at least one bonding pad 194 positioned on the seamless monolithic semiconductor substrate 170 to provide an electrical connection between the signal conditioner 160 and the remotely positioned electrical device. The electrical device, itself, can be, for example, a remote sensing monitor.

Preferably, the compact sensing apparatus 120 further comprises a mounting base 190 on which the seamless monolithic semiconductor substrate is positioned. The base can connect directly to the seamless monolithic semiconductor substrate 170 thereby providing support to the sensor 140 and signal conditioner 160 formed therein. The compact sensing apparatus 120 preferably includes as well a housing or encapsulation 196 encapsulating at least a portion of the signal conditioner 160 for providing a protective cover over the signal conditioner 160. The electrical conductor 192 preferably extends through the encapsulation 196 to thereby provide an electrical connection between the sensing apparatus 120 and preselected electrical device positioned outside the encapsulation 196 and remotely from the sensing apparatus 120.

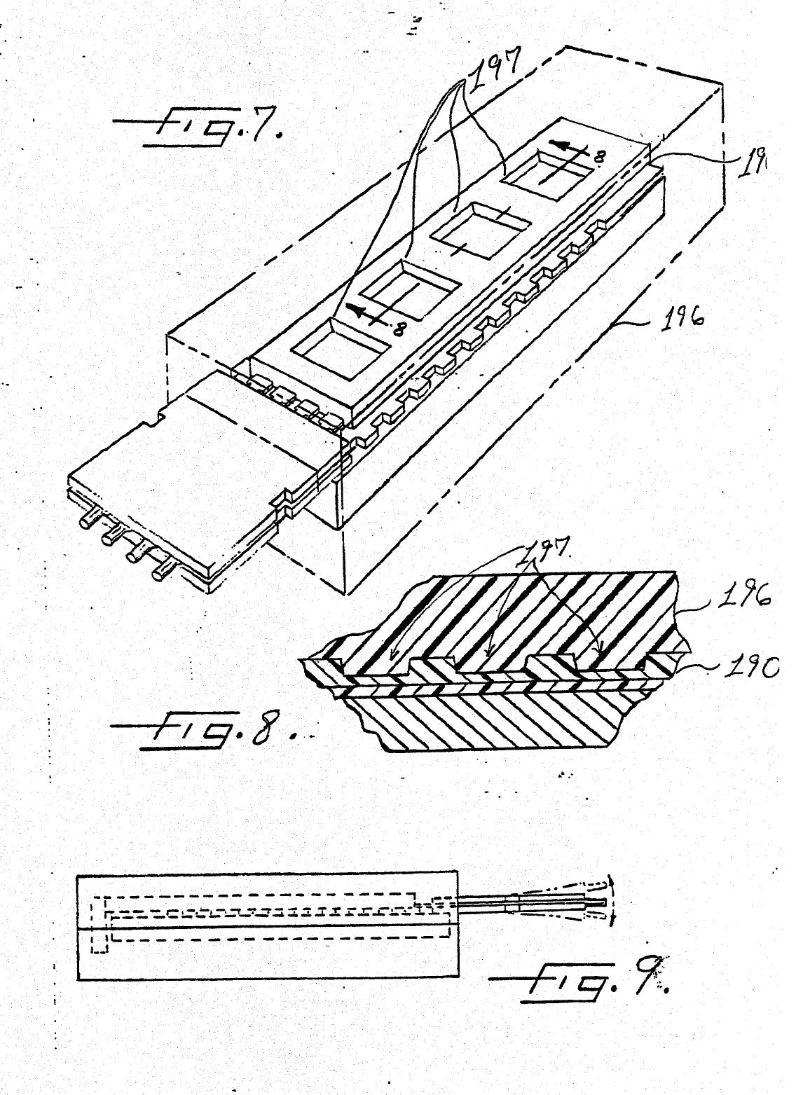

More specifically, as illustrated in FIGS. 4 and 5, the electrical conductor can be a flexible ribbon cable 190 having at least one conductor 192 encased within a ribbon cable cover and electrically connected to the signal conditioner 160 to thereby provide the electrical connection that provides the conductive path between the sensing apparatus 120 and the preselected electrical device positioned outside the encapsulation 196. Alternatively, however, the base can be a lead frame and the electrical conductor a plurality of pins extending from the frame and electrically connected to the signal conditioner 160 to thereby provide the electrical connection that provides the conductive path between the sensing apparatus 120 and the preselected electrical device positioned outside the encapsulation.

As with respect to the first embodiment, the compact sensing apparatus 120 permits the sensor 140 and the signal conditioner 160 to be oriented relative to each other by orienting the wafer surface 174 and the cut plane 172 of the seamless monolithic semiconductor substrate 170 as earlier described. As illustrated by way of example of FIG. 12, a perspective view of a sensing apparatus according to the present invention includes a predetermined angle (α) between an imaginary plane (I) parallel to a substantially planar open surface of a substrate 90 with referenced line (12) for defining angle α relative to cut plane 92. Again, the predetermined angle α, is greater than one hundred eighty (180) degrees. In many applications, the predetermined angle is at least about two hundred fifty (250) degrees but no greater than about two hundred ninety (290) degrees to thereby reduce the lengthwise extent of the sensing apparatus and to permit the sensor to be angled relative to the physical presence being sensed. In some applications, specifically, the predetermined angle a is as illustrated with reference to FIG. 12, about two hundred seventy (270) degrees to thereby minimize the lengthwise extent of the sensing apparatus and to permit the sensor to be angled relative to the physical presence being sensed.

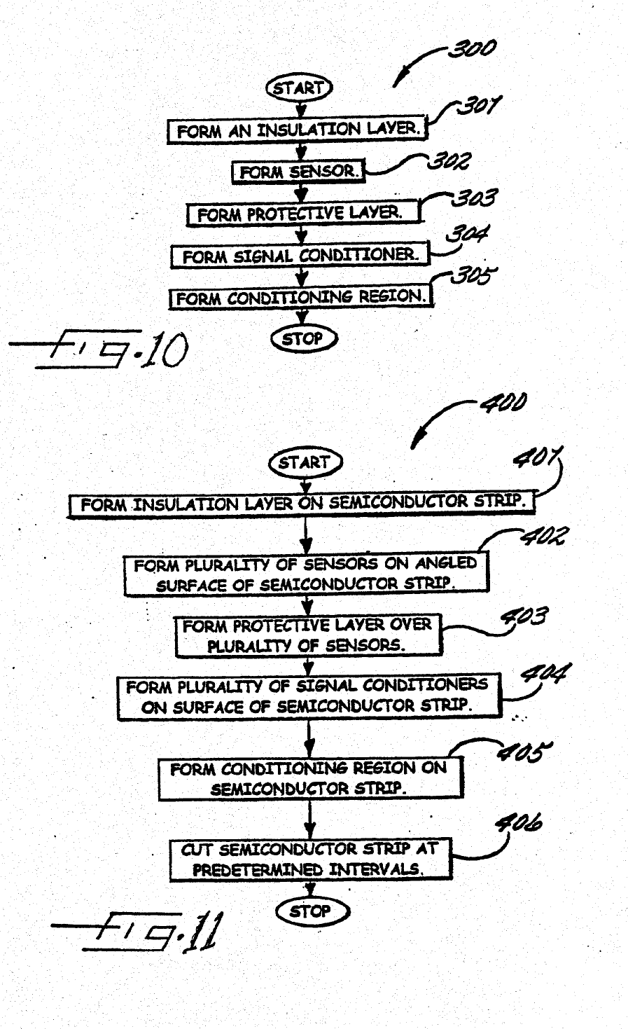

As further illustrated in FIGS. 5 and 6 the mounting base 190 further comprises a roughened surface portion 202 that contacts the encapsulation 196 to thereby increase friction between the base 190 and the encapsulation to thereby reduce the probability that the base 190 will separate from the encapsulation 196. The roughened surface portion 202, for example, can be one or more side portions marked by serrations as illustrated specifically in FIGS. 5 and 6. To further enhance the structural integrity by reducing the probability of separation of the encapsulation 196 from the base 190, the base preferably further comprises at least one encapsulation well 197 as illustrated in FIGS. 6 and 7. An encapsulation well 197, preferably formed in a portion of the base 190 provides a recess within which a portion of the encapsulation 196 extends. The at least one encapsulation well 197 thereby increases the amount of surface contact between the base 190 and the encapsulation 196 and accordingly reduces the probability that the encapsulation 196 will separate from the base 190.

Preferably, the seamless monolithic semiconductor substrate 90, 170 into which the sensor 60, 140 and signal conditioner 80, 160 of the sensing apparatus 40, 120 are formed has been cut from the wafer 100 using the concentrated energy of a laser to cut the wafer 100, the concentrated energy “slicing” the first substrate 90, 170 from the wafer 100 from which the monolithic substrate 90, 170 ultimately is formed as described above. The current industry standard for cutting wafers is to use a diamond saw. This conventional method of wafer cutting, however, generally causes interstitial damage to the substrate on the cut planes of the resulting substrate that is cut from the wafer. The surface anomalies that arise from such cutting can impede the flow of current through the semiconductor substrate. Ordinarily, this poses no problem because conventional methods for forming sensing and other semiconductor-based apparatuses do not form necessary circuitry on the cut planes of the substrate. According to the present invention, however, conductors and bonding pads are formed on a cut plane of semiconductor substrate so as to form a more compact sensing apparatus having an optimally angled sensor and signal conditioner. Preferably, therefore, the wafer 100 is cut by concentrated energy (e.g., coherent electromagnetic radiation generated by a laser) so as to cut the wafer 100 to form a first substrate 90, 170 having a cut plane 92, 172 formed by cuts induced by the concentrated energy used to separate the substrate 90, 170.

The laser, more specifically, delivers energy in the form of coherent electromagnetic radiation. This concentrated energy when imparted by the laser to the crystal lattice of the wafer at least partially serves to create a molecular structure more amenable to electrical conduction by healing cuts and alleviating cracks in the crystalline structure of the substrate 90, 170 and at least partially alleviating from the resulting monolithic semiconductor substrate 90, 170 surface anomalies that would impede the flow of current through polycrystalline conductors formed in the cut plane. To further facilitate formation of a molecular, crystalline structure conducive of electron flow, the monolithic semiconductor substrate 90, 170 preferably also has been annealed prior to forming the sensor 60, 140 and the signal conditioner 80, 160 therein.

Concentrated energy laser cutting, moreover, facilitates another feature of the present invention, namely forming the cut plane 92, 152 on which the sensor 60, 140 is formed at an angle relative to the wafer surface on which the signal conditioner is formed. Because the extent of the sensor 60, 140 and the signal conditioner 80, 160 are substantially parallel to the surfaces 92, 172 and 94, 174, respectively, in which each is formed, angling the cut plane relative to the wafer surface at the predetermined angle ensures that the sensor 60, 140 and the signal conditioner 80, 160 are likewise angled relative to each other substantially at the same predetermined angle.

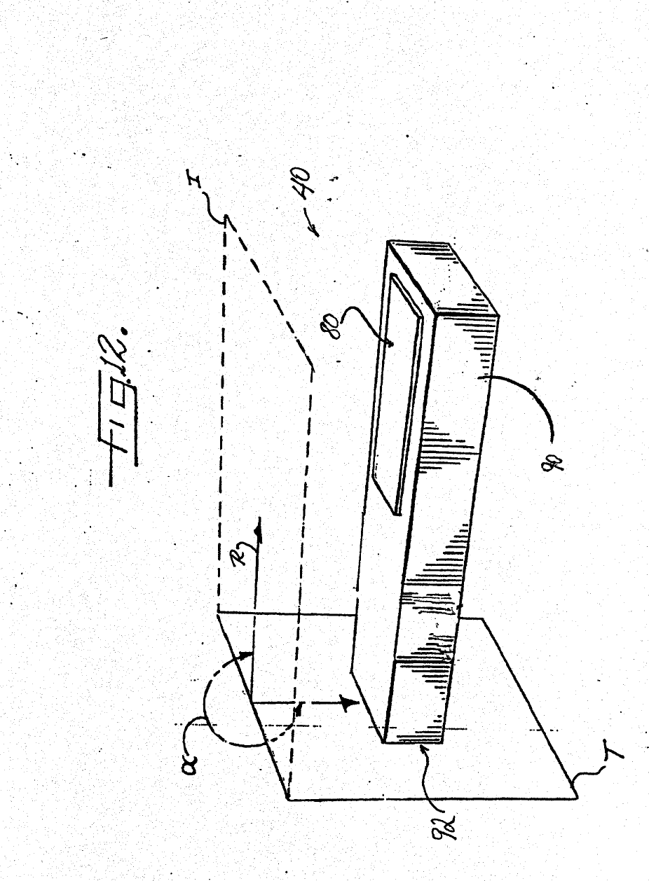

FIG. 10 illustrates method aspects of the present invention relating to the formation of sensing apparatus 40, 120 having a sensor 60, 140 and signal conditioner 80, 160 formed in a seamless monolithic semiconductor substrate 90, 170 and angled relative to each other at a predetermined angle. As described above, the sensor 60, 140 and signal conditioner 80, 160 are formed in a seamless monolithic substrate 90, 170 that has been cut from a semiconductor wafer 100. According to the method 300, the sensor 60, 140 and the signal conditioner 80, 160 are formed in separate discrete steps on distinct planar surfaces—the cut plane 92, 172 and the wafer surface 94, 174—of a single seamless semiconductor substrate 90, 170. This contrasts sharply with conventional methods in which the sensor and signal conditioning circuitry are formed substantially concurrently and on a common surface, the sensor and signal conditioning circuitry also being connected by metal conductors formed in essentially the same step and on the same surface as the sensor and signal conditioning circuitry.

Conventional methods require such near simultaneity in formation and surface positioning of circuitry because semiconductor devices require that the electrical junctions on and discrete semiconductor regions in the substrate of the device remain sharply defined if the device is to operate efficiently. High temperatures are a normal feature of methods for forming circuitry in a semiconductor substrate. Formation of distinct circuitry portions and their connection with metal conductors in a semiconductor substrate in successive steps at high temperatures poses a problem: separate formations of circuitry requiring dissimilar dopants or different concentrations of dopant would diffuse into one another under the high temperatures ordinarily required during each forming step. So, too, high temperatures would melt any metal conductors already formed in the substrate. One significant advantage of the method aspects of the present invention is that the sensor 60, 140 and signal conditioner 80, 160 are each formed in separate steps on distinct planar surfaces of the same seamless monolithic semiconductor substrate. As explained in detail below, the sensor 60, 140, preferably, is formed over an insulating layer that prevents undesired diffusion of semiconductor material into the seamless monolithic semiconductor substrate 90, 170 during subsequent formation of the signal conditioner 80, 160 on the wafer surface 94, 174 after the sensor 60, 140 has been formed on the cut plane 92, 172.

The method 300 specifically entails forming an insulation layer on a seamless monolithic semiconductor substrate prior to forming the sensor 60, 140 and polycrystalline conductors that will connect the sensor 60, 140 to the signal conditioner 80, 160, both the sensor 60, 140 and conductors being formed in the cut plane 92, 172 (Block 301). The insulating layer is formed behind the cut plane 92, 172 in the seamless monolithic semiconductor substrate 90, 170 and serves as a barrier between the cut plane 92, 172 in which the sensor is formed and the wafer surface 94, 174 in which the signal conditioner 80, 160 is formed. The insulating layer, more specifically, is formed from a material such as silicon oxide (SiO₂) and with sufficient thickness in the seamless monolithic semiconductor substrate 90, 170 as to prevent diffusion of semiconductor material used to form the sensor 60, 140 and conductors of polycrystalline material in the cut plane 92, 172 during subsequent formation of the signal conditioner 80, 160 in the wafer surface 94, 174 of the seamless monolithic semiconductor substrate 90, 170.

After formation of the insulating layer, the sensor 60, 140 and conductors connected to the sensor 60, 140 are formed in the cut plane 92, 172 of the seamless monolithic semiconductor substrate 90, 170 (Block 302). The sensor can be any device responsive to a predetermined physical stimulus, which generates a sensing signal in response to the physical stimulus. The sensor typically will comprise at least one rectangular or square conducting plate and at least one electrical connection attached thereto such that the sensor conducts electrons or holes thus serving as a current carrier as will be well understood by those skilled in the art. For example, the sensor may be a Hall cell having four electrical connections, one per side of a square plate. The sensor, alternatively, can be a capacitive sensor that typically has two plates, one typically be smaller than the other, and each having an signal conductor at an end thereof.

Yet a third example of a sensor is a strain gauge having conductors extending lengthwise thereto and forming electrical connections at each end. Still a fourth example of a sensor is an accelerometer or tilt sensor comprising a rectangular or square plate suspended over a recessed or voided portion in the substrate and having at least one electrical connection connected to each opposing side thereof. A portion of a conductive path between the sensor 60, 140 and the signal conditioner 80, 160 is formed by at least one polycrystalline conductor extending from an electrical connector of the sensor 60, 140. The polycrystalline conductor extends then along the cut plane 92, 172 from the sensor 60, 140 to the edge of seamless monolithic substrate where the cut plane 92, 172 meets the wafer surface 94, 174.

In a subsequent step of the method 300, preferably, a protective layer is formed over the sensor (Block 303). The signal conditioner 80, 160 is then formed during the next step of the method (Block 304). More specifically, the step entails etching away any passivation material that may be left from the prior forming steps and that may extend over the edge where the cut plane 92, 172 meets the wafer surface 94, 174, the material being the result. The signal conditioner 80, 160, preferably is formed with dopants and polycrystalline material in accordance with the precise properties desired for the signal conditioning circuitry as will be readily understood by those skilled in the art. Finally, a conditioning region is formed in which the conductive path between the sensor 60, 140 and the signal conditioner 80, 160 is completed by electrically connecting the polycrystalline conductors formed in the cut plane 92, 172 of the seamless monolithic semiconductor substrate 90, 170 to conductors extending along the wafer surface 94, 174 thereof and connected to the signal conditioner 80, 160.

Preferably, the conductors are metal conductors formed from a metal passivation layer formed on a portion of the wafer surface 94, 174 and then etched to leave metal traces defining metal conductors. The conductive path between the sensor 60, 140 and the signal conditioner, then is completed with at least one metal conductor connected to the signal conditioner 80, 160 and electrically connected at the edge of the substrate to at least one polycrystalline conductor connected to the sensor 60, 140, the edge again being the edge shared by the cut plane 92, 172 and the wafer surface 94, 174 of the seamless monolithic semiconductor substrate 90, 170.

This method aspect of the present invention further can comprise positioning the seamless monolithic semiconductor substrate 170 on a mounting base 190, encasing at least the signal conditioner 160 in an encapsulation 196, and connecting a conductor to a bonding pad 194 that is electrically connected to the signal conditioner to thereby permit the sensing apparatus 120 to be connected to a remote electrical device such as a sensing monitor. For example, the method can entail placing the monolithic semiconductor substrate on a flexible ribbon cable. Alternatively, the monolithic semiconductor substrate can be placed on a lead frame with metal pins. Further, with respect to the substrate mounted on a flexible ribbon cable, for example, the encapsulation 196 can be formed by placing the seamless monolithic semiconductor substrate 170 having a sensor 140 and signal conditioner 180 formed therein in a plastic molding machine that will mold a cylindrically shaped housing around the substrate with the sensor 140 at one end of the cylindrical housing and the ribbon cable extending outwardly from an opposing end thereof. With respect to the seamless monolithic semiconductor substrate 170 having a sensor 140 and signal conditioner 180 formed therein and mounted on a lead frame, the frame and pins connected thereto can be encapsulated in an industry-standard transistor package such as the TO-92 or TO-110 type familiar to those skilled in the art.

FIG. 11 illustrates an additional method aspect of the present invention, the method directed to efficiently forming a plurality of sensing apparatuses, each having a sensor 60, 108 and signal conditioner 80, 104 angled relative to each other at a predetermined angle and formed in a seamless monolithic semiconductor substrate 90, 110. A preferred method 400 for forming the plurality of sensing devices according to present invention entails slicing a semiconductor wafer 100 as described above, preferably using laser cutting methods. The wafer is sliced to form one or more primary semiconductor substrates 106 having a lateral extent corresponding to the length of the wafer surface 94, 174 in which the signal conditioner 80, 160 will be formed. (See FIGS. 1 and 2.) Preferably, a plurality of such primary substrates will be formed, each having a lateral extent corresponding to the length of the wafer surface in which a signal conditioner will be formed. Moreover, each substrate preferably will be annealed as earlier described so as to at least partially alleviate cracks that otherwise could propagate through the substrate. The plurality of primary substrates 106 can be turned on end and stacked closely together, the substrates being held, for example, by a metal band attached around the outer edges of the strips with lips folded over the strips.

As illustrated in FIG. 11, the method 400 further entails forming an insulating layer as already described on a portion of each substrate to prevent diffusion of semiconductor and other polycrystalline materials during the formation of signal conditioning circuitry after sensors have been formed on cut planes 109 of the plurality of semiconductor substrates 106 (Block 401). A plurality of sensors 60, 108 are then formed spaced apart in the cut planes 92, 109 of the substrates 106 (Block 402). Polycrystalline conductors corresponding to each of the sensors 60, 108 are also formed in the cut planes 109 of the plurality of semiconductor substrates 106. A protective layer is formed over the sensors 60, 108 (Block 403). Each of the plurality of substrates 106 is again turned, preferably to lie flat on a plate and held in place using, for example, an epoxy. A plurality of signal conditioners 104 is formed in the wafer surfaces 107 of the plurality of semiconductor substrates 106 (Block 404). The plurality of signal conditioners 104 preferably is each formed with dopant and/or polycrystalline materials as will be understood by those skilled in the art. A metal passivation layer is formed on the substrates 106 and then etched to leave metal traces forming metal conductors connected to the signal conditioners 80, 104. A conditioning regions is formed in the semiconductor substrate so as to connect to the polycrystalline conductors formed in the cut planes 109 of the substrates 106 the metal conductors formed on the wafer surfaces 107 of the plurality of semiconductor substrates 106 (Block 405). The polycrystalline conductors and the metal conductors jointly form conductive paths between each of the sensors 60, 108 and corresponding signal conditioners 80, 104 as described above. Finally, each of the substrates 106 is cut between each of the spaced-apart sensors 60, 108 and its corresponding signal conditioner 80, 104 to thereby yield a plurality of seamless monolithic semiconductor substrates 90, 110, each having a sensor 60, 108 and signal conditioner 80, 104 angled relative to each other at a predetermined angle.

In the drawings and specification, there have been disclosed a typical preferred embodiment of the invention, and although specific terms are employed, the terms are used in a descriptive sense only and not for purposes of limitation. The invention has been described in considerable detail with specific reference to these illustrated embodiments. It will be apparent, however, that various modifications and changes can be made within the spirit and scope of the invention as described in the foregoing specification and as defined in the appended claims.

That claimed is:

1. A method for forming a circuit on a seamless monolithic semiconductor substrate, the method comprising:
forming a first portion of the circuit in a cut plane of the seamless monolithic semiconductor substrate;
forming a second portion of the circuit in a wafer surface of the same seamless monolithic semiconductor substrate;
electrically connecting the first portion of the circuit formed in the cut plane of the seamless monolithic semiconductor substrate to the second portion of the circuit formed in the wafer surface of the same seamless monolithic semiconductor substrate.

2. A method for forming a circuit on a seamless monolithic semiconductor substrate as defined in claim 1, wherein the steps of forming the first and second portions of the circuit in the substrate are preformed sequentially, the first portion of the circuit being formed in the substrate prior to forming the second portion, and wherein the method further comprises forming an insulating layer in the substrate prior to formation of the first and second portions of the circuit.

3. A method for forming a circuit on a seamless monolithic semiconductor substrate as defined in claim 2, wherein the insulating layer is formed to have a predetermined thickness sufficient to prevent diffusion of semiconductor dopants when the first and second portions of the circuit are at least partially formed by doping the seamless monolithic semiconductor and subjecting the substrate to high temperatures and when each circuit portion is formed with a different dopant composition.

4. A method for forming a circuit on a seamless monolithic semiconductor substrate as defined in claim 2, wherein the insulating layer is formed to have a predetermined thickness sufficient to prevent diffusion of semiconductor dopants when the first and second portions of the circuit are at least partially formed by doping the seamless monolithic semiconductor and subjecting the substrate to high temperatures and when each circuit portion is formed with different concentrations of dopant material.

5. A method for forming a circuit on a seamless monolithic semiconductor substrate as defined in claim 2, wherein the step of electrically connecting the first and second portions of the circuit comprise forming a first electrical conductor that is electrically connected to the first circuit portions and extends along the cut plane of the seamless monolithic semiconductor substrate, forming a second electrical conductor that is electrically connected to the second circuit portion and extends along the wafer surface of the same substrate, and connecting the first and second conductor at an edge of the substrate, the substrate edge being between the cut plane and the wafer surface of the substrate.

6. A method for forming a circuit on a seamless monolithic semiconductor substrate as defined in claim 5, wherein at least one of the first and second electrical conductors is formed by doping the seamless monolithic semiconductor substrate to form a conductive path composed of a polycrystalline material.

7. A method for forming a circuit on a seamless monolithic semiconductor substrate as defined in claim 5, wherein the first electrical conductor is formed by doping the seamless monolithic semiconductor substrate to form a conductive path composed of a polycrystalline material, and the second electrical conductor is formed by applying a metal layer to the seamless monolithic semiconductor substrate and etching the metal layer to form a conductive path composed of a metal.

8. A method for forming a circuit on a seamless monolithic semiconductor substrate as defined in claim 1, wherein the method further comprises forming the first and second circuit portions in a seamless monolithic semiconductor substrate formed from a wafer of semiconductor material, the substrate formed by cutting the wafer with coherent electromagnetic radiation generated by and focused on the wafer by a laser.

9. A method for forming a compact sensing apparatus having a sensor formed in a seamless monolithic semiconductor substrate and a signal conditioner formed in the same substrate and electrically connected to the sensor, the method comprising the steps of:
forming a sensor on a cut plane of the seamless monolithic semiconductor to form a circuit for generating a sensing signal in response to a predetermined physical stimulus;
forming a signal conditioner on a wafer surface of the same seamless monolithic semiconductor substrate by doping the substrate to form a circuit for conditioning the sensing signal; and
electrically connecting the sensor to the signal conditioner.

10. A method for forming a compact sensing apparatus as defined in claim 9, wherein the steps of forming the sensor and the signal conditioner are performed sequentially, the sensor being formed prior to forming the signal conditioner.

11. A method for forming a compact sensing apparatus as defined in claim 10, the method further comprises forming an insulating layer in the seamless monolithic semiconductor substrate prior to formation of the sensor, the insulating layer positioned to insulate the cut plane from other portions of the substrate.

12. A method for forming a compact sensing apparatus as defined in claim 11, the method further comprising forming a protective passivation layer over the sensor after the sensor is formed on the cut plane of the seamless monolithic semiconductor substrate and prior to forming the signal conditioner on the wafer surface of the seamless monolithic semiconductor substrate to thereby provide at least a partial protective cover over the sensor.

13. A method for forming a compact sensing apparatus as defined in claim 12, the method further comprising forming at least one cut plane conductor on the cut plane of the seamless monolithic semiconductor substrate, the at least one cut plane conductor being electrically connected to the sensor and extending from the sensor over the cut plane to an edge of the seamless monolithic semiconductor substrate, the edge being the edge shared by the cut plane and the wafer surface of the substrate.

14. A method for forming a compact sensing apparatus as defined in claim 13, the method further comprising forming at least one wafer surface conductor on the wafer surface of the seamless monolithic semiconductor substrate, the at least one wafer surface conductor being electrically connected to the signal conditioner and extending from the signal conditioner over the wafer surface to an edge of the seamless monolithic semiconductor substrate, the edge being the edge shared by the cut plane and the wafer surface of the substrate.

15. A method for forming a compact sensing apparatus as defined in claim 14, wherein the step of electrically connecting the sensor and the signal conditioner comprises connecting the at least one cut plane conductor to a corresponding wafer surface conductor, the connection being made at the edge of the seamless monolithic semiconductor substrate which is shared by the cut plane and the wafer surface.

16. A method for forming a circuit on a seamless monolithic semiconductor substrate as defined in claim 15, wherein the cut plane conductor is formed by doping the seamless monolithic semiconductor substrate to form at least one conductive path composed of a polycrystalline material.

17. A method for forming a circuit on a seamless monolithic semiconductor substrate as defined in claim 16, wherein the wafer surface conductor is formed by applying a metal layer to the wafer surface of the seamless monolithic semiconductor substrate and etching the metal layer to form a conductive path composed of a metal.

18. A method for forming a compact sensing apparatus as defined in claim 17, wherein the insulating layer is formed to have a predetermined thickness sufficient to prevent diffusion of semiconductor dopants through the insulating layer when the seamless monolithic semiconductor is subjected to temperatures in a preselected range.

19. A method for forming a compact sensing apparatus as defined in claim 18, wherein the insulating layer is formed to have a predetermined thickness sufficient to prevent diffusion of semiconductor dopants at high temperatures when the at least one cut plane conductor and the signal conditioner are each formed with different dopant materials.

20. A method for forming a compact sensing apparatus as defined in claim 18, wherein the insulating layer is formed to have a predetermined thickness sufficient to prevent diffusion of semiconductor dopants at high temperatures when the at least one cut plane conductor and the signal conditioner are each formed with different concentrations of dopant material.

21. A method for forming a compact sensing apparatus as defined in claim 9, wherein the method further comprises forming the sensor and the signal conditioner in a seamless monolithic semiconductor substrate formed from a wafer of semiconductor material, the substrate formed by cutting the wafer with coherent electromagnetic radiation generated by and focused on the wafer by a laser.

22. A method for forming a compact sensing apparatus having a sensor responsive to a predetermined physical stimulus and a signal conditioner electrically connected to the sensor for conditioning a signal generated by the sensor, the method comprising the steps of:
forming a sensor for generating a sensing signal in response to a predetermined physical stimulus, the sensor formed in a first surface of a seamless monolithic semiconductor substrate; and
forming a signal conditioner for conditioning the sensing signal generated by the sensor, the signal conditioner electrically connected to the sensor and being formed in a second surface of the same seamless monolithic semiconductor substrate.

23. A method for forming a compact sensing apparatus as defined in claim 22, the method further comprising orienting the sensor and the signal conditioner relative to each other at a predetermined angle greater than one hundred eighty (180) degrees, the predetermined angle being defined as the angle of rotation between an imaginary initial plane extending substantially parallel to the senor and an imaginary terminal plane extending substantially parallel to the signal conditioner.

24. A method for forming a compact sensing apparatus as defined in claim 23, wherein the step of orienting the sensor and the signal conditioner relative to each other comprises forming the sensor and the signal conditioner on a seamless monolithic semiconductor substrate having the first plane oriented with respect to the second plane at the predetermined angle.

25. A method for forming a compact sensing apparatus as defined in claim 24, wherein the predetermined angle is more than about two hundred fifty (250) degrees but less than about two hundred ninety (290) degrees.

26. A method for forming a compact sensing apparatus as defined in claim 25, wherein the predetermined angle is about two hundred seventy (270) degrees to thereby orient the sensor and the signal conditioner orthogonally with respect to each other.

27. A method for forming a compact sensing apparatus as defined in claim 22, wherein the steps of forming the sensor and the signal conditioner are performed sequentially, the sensor portion being formed prior to the signal conditioner being formed.

28. A method for forming a compact sensing apparatus as defined in claim 27, wherein the method further comprises forming an insulating layer in the seamless monolithic semiconductor substrate prior to formation of the sensor, the insulating layer being positioned to insulate the first surface from the second surface of the seamless monolithic semiconductor substrate.

29. A method for forming a compact sensing apparatus as defined in claim 28, wherein the insulating layer is formed to have a predetermined thickness sufficient to prevent diffusion of semiconductor dopants between the first surface and the second surface when the seamless monolithic semiconductor substrate is subjected to temperatures of a preselected range.

30. A method for forming a compact sensing apparatus as defined in claim 29, wherein the sensor and the signal conditioner are electrically connected by a conductive path formed by a first electrical conductor and a second electrical conductor, the first electrical conductor electrically connected to the sensor and extending along the first surface of the seamless monolithic semiconductor substrate, the second electrical conductor electrically connected to the signal conditioner and extending along the second surface of the substrate, and the first conductor connected to the second conductor at an edge of the substrate, the substrate edge being between the first surface and the second surface of the substrate.

31. A method for forming a compact sensing apparatus as defined in claim 30, wherein the first electrical conductor is formed by doping the seamless monolithic semiconductor substrate to form a conductive path composed of a polycrystalline material.

32. A method for forming a compact sensing apparatus as defined in claim 31, wherein the second electrical conductor is formed by applying a metal layer to the seamless monolithic semiconductor substrate and etching the metal layer to form a conductive path composed of a metal.

33. A method for forming a compact sensing apparatus as defined in claim 32, wherein the method further comprises forming the sensor and the signal conditioner in a seamless monolithic semiconductor substrate formed from a wafer of semiconductor material, the substrate formed by cutting the wafer with coherent electromagnetic radiation generated by and focused on the wafer by a laser.
